(19) United States
(12) Patent Application Publication
(10) Pub. No.: US 2026/0351292 A1
(43) Pub. Date: Nov. 5, 2026

(54) SEMICONDUCTOR MEMORY DEVICE

(71) Applicant: Kioxia Corporation, Tokyo (JP)

(72) Inventors: Yoko YOSHIMURA, Yokkaichi (JP); Kunifumi SUZUKI, Yokkaichi (JP); Kiwamu SAKUMA, Yokkaichi (JP); Yasunao OTSUKI, Yokkaichi (JP); Hidesato ISHIDA, Yokkaichi (JP)

(21) Appl. No.: 19/332,401

(22) Filed: Sep. 18, 2025

(30) Foreign Application Priority Data
Mar. 17, 2025 (JP) 2025-042507

(51) Int. Cl. G11C 5/06; G11C 11/22; G11C 16/04; H10B 53/10; H10B 53/20; H10D 30/01; H10D 30/69

(52) U.S. Cl. CPC G11C 5/063; G11C 11/2273; G11C 11/2275; G11C 16/0483; H10B 53/10; H10B 53/20; H10D 30/0415; H10D 30/701

(57) ABSTRACT

A semiconductor memory device includes a stacked body in which a plurality of electrode layers are stacked with an insulating layer interposed therebetween, an electrode film extending in a stacking direction inside the stacked body, a ferroelectric film and a first insulating film each arranged between the electrode layer and the electrode film, a bit line provided outside of the stacked body and connected to one end of the electrode film, and a source line provided outside of the stacked body and connected to the other end of the electrode film. A memory cell is provided at a position at which the electrode layer and the electrode film intersect each other. In the memory cell, a select transistor including a second insulating film that is non-ferroelectric instead of including the ferroelectric film is provided between the electrode layer and the electrode film.

### CROSS-REFERENCE TO RELATED APPLICATION

This application is based upon and claims the benefit of priority from Japanese Patent Application No. 2025-042507, filed Mar. 17, 2025, the entire contents of which are incorporated herein by reference.

### FIELD

Embodiments described herein relate generally to a semiconductor memory device.

### BACKGROUND

In a semiconductor memory device provided with a memory cell using a ferroelectric film, information is written in or erased from the memory cell according to a direction of an electric field applied to the ferroelectric film. While semiconductor memory devices using the ferroelectric film have characteristics in which a low voltage operation can be executed, the semiconductor memory device tends to have a small margin of a write voltage and a read voltage. Therefore, variation may occur in an on-current of a select transistor provided in the semiconductor memory device, leading to read errors.

### DESCRIPTION OF THE DRAWINGS

FIG. 1 is a perspective view illustrating a configuration of a semiconductor memory device according to a first embodiment;

FIG. 2 is a block diagram illustrating the configuration of the semiconductor memory device according to the first embodiment;

FIG. 3 is a circuit diagram illustrating a configuration of a memory cell array provided in the same semiconductor memory device;

FIG. 4 is a partial sectional view illustrating a configuration of the memory cell array provided in the same semiconductor memory device;

FIG. 5 is a partial sectional view taken along a line A-A of FIG. 4;

FIGS. 6A to 6C are perspective views illustrating a direction of a crystal axis of a ferroelectric film provided in the same memory cell array;

FIG. 7 is a diagram illustrating an operation characteristics of the same memory cell;

FIG. 8 is a circuit diagram illustrating a read operation of a select transistor provided in the memory cell array;

FIG. 9 is a circuit diagram illustrating an erase operation of the select transistor provided in the memory cell array;

FIG. 10 is a sectional view illustrating a configuration of a memory cell array according to a second embodiment;

FIG. 11A is a sectional view illustrating a first example of a manufacturing method for the memory cell array according to the first embodiment;

FIG. 11B is a sectional view illustrating the first example of the manufacturing method for the memory cell array according to the first embodiment;

FIG. 11C is a sectional view illustrating the first example of the manufacturing method for the memory cell array according to the first embodiment;

FIG. 11D is a sectional view illustrating the first example of the manufacturing method for the memory cell array; according to the first embodiment

FIG. 11E is a sectional view illustrating the first example of the manufacturing method for the memory cell array according to the first embodiment;

FIG. 11F is a sectional view illustrating the first example of the manufacturing method for the memory cell array according to the first embodiment;

FIG. 11G is a sectional view illustrating the first example of the manufacturing method for the memory cell array according to the first embodiment;

FIG. 11H is a sectional view illustrating the first example of the manufacturing method for the memory cell array according to the first embodiment;

FIG. 11I is a sectional view illustrating the first example of the manufacturing method for the memory cell array according to the first embodiment;

FIG. 12A is a sectional view illustrating a first example of a manufacturing method for a memory cell array having a configuration similar to the first embodiment;

FIG. 12B is a sectional view illustrating the first example of the manufacturing method for the memory cell array having a configuration similar to the first embodiment;

FIG. 12C is a sectional view illustrating the first example of the manufacturing method for the memory cell array having a configuration similar to the first embodiment;

FIG. 12D is a sectional view illustrating the first example of the manufacturing method for the memory cell array having a configuration similar to the first embodiment;

FIG. 12E is a sectional view illustrating the first example of the manufacturing method for the memory cell array having a configuration similar to the first embodiment;

FIG. 12F is a sectional view illustrating the first example of the manufacturing method for the memory cell array having a configuration similar to the first embodiment;

FIG. 12G is a sectional view illustrating the first example of the manufacturing method for the memory cell array having a configuration similar to the first embodiment;

FIG. 12H is a sectional view illustrating the first example of the manufacturing method for the memory cell array having a configuration similar to the first embodiment;

FIG. 12I is a sectional view illustrating the first example of the manufacturing method for the memory cell array having a configuration similar to the first embodiment;

FIG. 12J is a sectional view illustrating the first example of the manufacturing method for the memory cell array having a configuration similar to the first embodiment;

FIG. 13A is a sectional view illustrating a first example of a manufacturing method for the memory cell array according to the second embodiment;

FIG. 13B is a sectional view illustrating the first example of the manufacturing method for the memory cell array according to the second embodiment;

FIG. 13C is a sectional view illustrating the first example of the manufacturing method for the memory cell array according to the second embodiment;

FIG. 13D is a sectional view illustrating the first example of the manufacturing method for the memory cell array according to the second embodiment;

FIG. 13E is a sectional view illustrating the first example of the manufacturing method for the memory cell array according to the second embodiment;

FIG. 13F is a sectional view illustrating the first example of the manufacturing method for the memory cell array according to the second embodiment;

FIG. 13G is a sectional view illustrating the first example of the manufacturing method for the memory cell array according to the second embodiment;

FIG. 13H is a sectional view illustrating the first example of the manufacturing method for the memory cell array according to the second embodiment;

FIG. 13I is a sectional view illustrating the first example of the manufacturing method for the memory cell array according to the second embodiment;

FIG. 13J is a sectional view illustrating the first example of the manufacturing method for the memory cell array according to the second embodiment;

FIG. 14A is a sectional view illustrating a second example of the manufacturing method for the memory cell array according to the second embodiment;

FIG. 14B is a sectional view illustrating the second example of the manufacturing method for the memory cell array according to the second embodiment;

FIG. 14C is a sectional view illustrating the second example of the manufacturing method for the memory cell array according to the second embodiment;

FIG. 14D is a sectional view illustrating the second example of the manufacturing method for the memory cell array according to the second embodiment;

FIG. 14E is a sectional view illustrating the second example of the manufacturing method for the memory cell array according to the second embodiment;

FIG. 14F is a sectional view illustrating the second example of the manufacturing method for the memory cell array according to the second embodiment;

FIG. 14G is a sectional view illustrating the second example of the manufacturing method for the memory cell array according to the second embodiment;

FIG. 14H is a sectional view illustrating the second example of the manufacturing method for the memory cell array according to the second embodiment;

FIG. 14I is a sectional view illustrating the second example of the manufacturing method for the memory cell array according to the second embodiment;

FIG. 14J is a sectional view illustrating the second example of the manufacturing method for the memory cell array according to the second embodiment;

FIG. 15A is a sectional view illustrating a third example of the manufacturing method for the memory cell array according to the second embodiment;

FIG. 15B is a sectional view illustrating the third example of the manufacturing method for the memory cell array according to the second embodiment;

FIG. 15C is a sectional view illustrating the third example of the manufacturing method for the memory cell array according to the second embodiment;

FIG. 15D is a sectional view illustrating the third example of the manufacturing method for the memory cell array according to the second embodiment;

FIG. 15E is a sectional view illustrating the third example of the manufacturing method for the memory cell array according to the second embodiment;

FIG. 15F is a sectional view illustrating the third example of the manufacturing method for the memory cell array according to the second embodiment;

FIG. 15G is a sectional view illustrating the third example of the manufacturing method for the memory cell array according to the second embodiment; and

FIG. 15H is a sectional view illustrating the third example of the manufacturing method for the memory cell array according to the second embodiment.

### DETAILED DESCRIPTION

Embodiments provide a semiconductor memory device that includes a memory cell using a ferroelectric film, in which stability of operations including writing and reading is improved while reducing a variation in an on-current of a select transistor.

In general, according to one embodiment, a semiconductor memory device includes a stacked body in which a plurality of electrode layers are stacked with insulating layers interposed therebetween. The same semiconductor memory device includes an electrode film extending in a stacking direction inside the stacked body, and a ferroelectric film and a first insulating film each arranged between the electrode layer and the electrode film. The same semiconductor memory device includes a bit line provided outside of the stacked body and connected to one end of the electrode film, and a source line provided outside of the stacked body and connected to the other end of the electrode film. In the same semiconductor memory device, a memory cell is provided at a position at which the electrode layer and the electrode film intersect each other via the ferroelectric film and the first insulating film in the stacked body. In the same semiconductor memory device, in the memory cell closest to the bit line, a select transistor including a second insulating film that is non-ferroelectric instead of including the ferroelectric film is provided between the electrode layer and the electrode film.

Hereinafter, a semiconductor memory device according to embodiments will be described in detail with reference to the attached drawings. The present disclosure is not limited to the embodiments.

### First Embodiment

A semiconductor memory device according to a first embodiment is provided with a memory cell using a ferroelectric film, and information is written or erased according to a direction of an electric field applied to the ferroelectric film. Measures are taken to improve reliability of operations including writing and erasing.

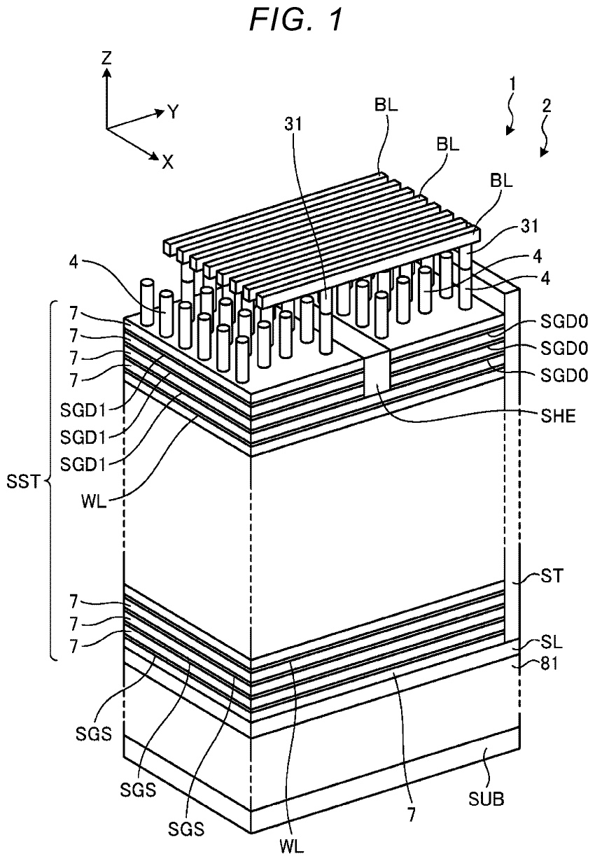

A semiconductor memory device 1 may have a configuration illustrated in FIG. 1. FIG. 1 is a perspective view illustrating a configuration of the semiconductor memory device 1.

The semiconductor memory device 1 is a three-dimensional semiconductor memory and is, for example, a ferroelectric memory. The semiconductor memory device 1 includes a memory cell array 2, a word line WL, a select gate line SGD, a select gate line SGS, a bit line BL, and a source line SL. Hereinafter, an extending direction of the bit line BL is referred to as a Y direction, a stacking direction of a memory cell transistor is referred to as a Z direction, and a direction perpendicular to the Y direction and the Z direction is referred to as an X direction.

The select gate line SGS is stacked on a substrate SUB with an insulating layer 7 interposed therebetween. In the example illustrated in FIG. 1, three select gate lines SGS are provided. The word line WL is stacked on the uppermost select gate line SGS with the insulating layer 7 interposed therebetween. In the example illustrated in FIG. 1, a plurality of layers of word lines WL are alternately provided with the insulating layers 7 in the Z direction. The select gate line SGD is stacked on the uppermost word line WL with the insulating layer 7 interposed therebetween. The select gate line SGS, the word line WL, and the select gate line SGD are each formed in a plate shape extending in the X direction and the Y direction.

In the example of FIG. 1, the select gate line SGD, the word line WL, and the select gate line SGS are separated and insulated in the Y direction by slits ST. The source line SL is disposed on the +Z side of the substrate SUB with an interlayer insulating film 81 interposed therebetween. The slit ST is provided on the +Z side of the source line SL and extends in the X direction and the Z direction.

The select gate lines SGD are separated in the Y direction by, for example, separation films SHE. In the example of FIG. 1, select gate lines SGD0 and SGD1 divided in the Y direction are illustrated.

The separation film SHE is provided above (on the +Z side of) the word line WL and extends in the X direction and the Z direction. Therefore, the select gate lines SGD0 and SGD1 are arranged on the word line WL side by side in the Y direction. In the example of FIG. 1, three layers are provided for each of the select gate lines SGD0 and SGD1.

The substrate SUB is, for example, a silicon substrate. The select gate line SGS, the word line WL, and the select gate line SGD may be formed with, for example, a material of which a main component is metal such as tungsten (W). The insulating layer 7 and the interlayer insulating film 81 may be formed with, for example, an insulator such as silicon oxide.

The semiconductor memory device 1 further includes a plurality of columnar bodies 4. The columnar body 4 penetrates through the select gate line SGS, the word line WL, and the select gate line SGD and extends in the Z direction that is the stacking direction of the lines. A plurality of bit lines BL are provided above the select gate line SGD. The plurality of bit lines BL each extend in the Y direction and are arranged to be spaced in the X direction.

Each of the columnar bodies 4 is electrically connected to the bit line BL via a contact plug 31. For example, one of the columnar bodies 4 sharing the select gate line SGD0 and one of the columnar bodies 4 sharing the select gate line SGD1 are electrically connected to one bit line BL. Each columnar body 4 includes a columnar channel region.

In FIG. 1, to simplify illustration, an interlayer insulating film provided between the select gate line SGD and the bit line BL is omitted.

In the semiconductor memory device 1, each of the select gate line SGD, the word line WL, and the select gate line SGS is formed with a conductive layer. On the +Z side of the source line SL, a stacked body SST in which a conductive layer and an insulating layer are alternately stacked is configured. The columnar channel region of the columnar body 4 is configured with a semiconductor film. The stacked body SST is penetrated by the columnar body 4 and configures an array of three-dimensional memory cells (the memory cell array 2).

That is, in the semiconductor memory device 1, portions in which the word lines WL intersect the columnar bodies 4 are configured to function as memory cells, thereby configuring the memory cell array 2 in which the plurality of memory cells are arranged three-dimensionally. Portions in which the select gate lines SGS intersect the columnar bodies 4 function as source-side select gates, and portions in which the select gate lines SGD0 and SGD1 intersect the columnar bodies 4 function as drain-side select gates. In the semiconductor memory device 1, by increasing the number of stacked word lines WL in the stacked body SST, storage capacity can be increased without using more fine patterning technology.

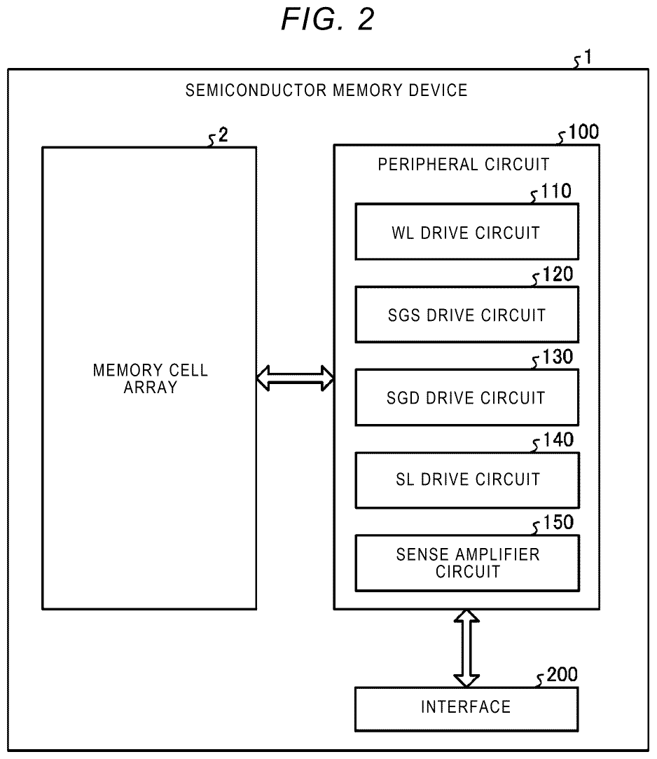

FIG. 2 is a block diagram illustrating the schematic configuration of the semiconductor memory device 1. As illustrated in FIG. 2, the semiconductor memory device 1 includes the memory cell array 2, a peripheral circuit 100, and an interface 200. The peripheral circuit 100 includes a WL drive circuit 110, an SGS drive circuit 120, an SGD drive circuit 130, an SL drive circuit 140, and a sense amplifier circuit 150.

The WL drive circuit 110 is a circuit that controls a voltage applied to the word line WL. The SGS drive circuit 120 is a circuit that controls a voltage applied to the select gate line SGS. The SGD drive circuit 130 is a circuit that controls a voltage applied to the select gate line SGD. The SL drive circuit 140 is a circuit that controls a voltage applied to the source line SL. The sense amplifier circuit 150 is a circuit that controls a voltage applied to the bit line BL and determines data read according to a signal from a selected memory cell.

The peripheral circuit 100 controls an operation of the semiconductor memory device 1 based on an instruction input via the interface 200 from outside (for example, a memory controller of a memory system to which the semiconductor memory device 1 is applied).

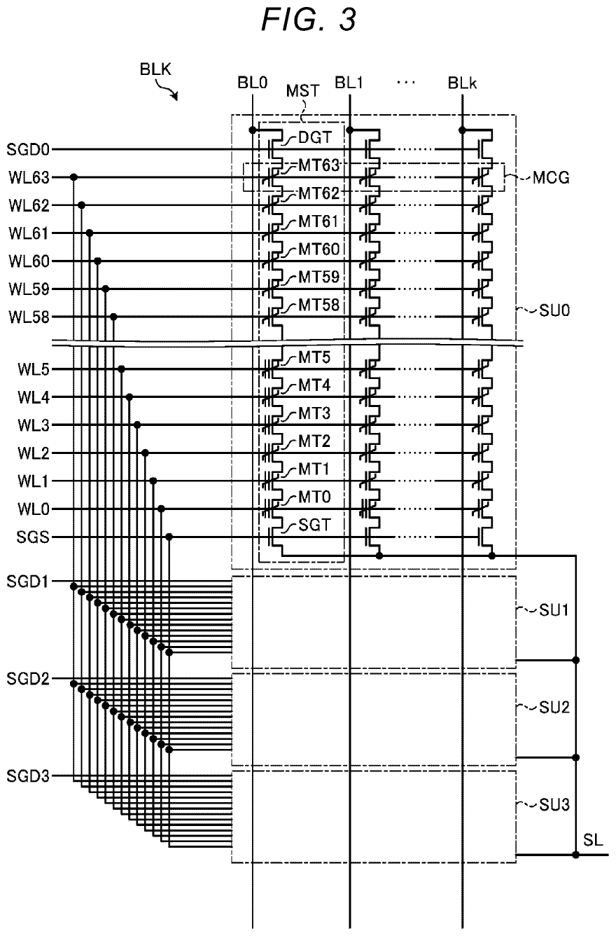

Next, a circuit configuration of the memory cell array 2 will be described with reference to FIG. 3. FIG. 3 is a circuit diagram illustrating the configuration of the memory cell array 2.

The memory cell array 2 includes a plurality of blocks BLK as a set including a plurality of memory cell transistors MT. Hereinafter, the memory cell transistor MT is simply referred to as a memory cell MT.

Each block BLK includes a plurality of string units SU0, SU1, SU2, and SU3 as sets each including the memory cells MT associated with the word lines WL and the bit lines BL. Each block BLK is associated with, for example, 64 word lines WL0 to WL63 and k+1 bit lines BL0 to BLk. Here, k is any integer of 2 or more.

Each of the string units SU0 to SU3 includes a plurality of memory strings MST in which the memory cells MT are connected in series. In FIG. 3, four string units SU0 to SU3 are illustrated as an example, but the number of string units SU0 to SU3 may be two or less or may be four or more. The number of memory strings MST in the string unit SU is freely selected.

The plurality of string units SU0, SU1, SU2, and SU3 each correspond to a plurality of select gate lines SGD0, SGD1, SGD2, and SGD3 and share the select gate line SGS, thereby functioning as a plurality of drive units in the block BLK. Each string unit SU can be driven with the corresponding select gate line SGD and the select gate line SGS. Each string unit SU includes the plurality of memory strings MST.

Each memory string MST includes the memory cells MT at positions intersecting the word lines WL. For example, each memory string MST includes 64 memory cells MT (MT0 to MT63) and select transistors DGT and SGT.

The memory cell MT includes a ferroelectric film and a first insulating film between an electrode layer and an electrode film and can write or erase information according to a direction of an electric field applied to the ferroelectric film via the electrode layer and the electrode film.

The electrode layer corresponds to the word line WL and the electrode film corresponds to a channel region connected in a string shape to the bit line BL, as will be described below.

The 64 memory cells MT (MT0 to MT63) are connected in series between a source of the select transistor DGT and a drain of the select transistor SGT. The number of memory cells MT in the memory string MST is not limited to 64.

Gates of the select transistors DGT in the string units SU0 to SU3 are each connected to gate lines SGD0 to SGD3. Meanwhile, gates of the select transistors SGT in each string unit are commonly connected to, for example, the select gate line SGS.

Drains of the select transistors DGT of the memory strings MST in the string units SU are each connected to different bit lines BL0 to BLk. The bit lines BL0 to BLk are commonly connected to one memory string MST in each string unit SU between the plurality of blocks BLK. A source of each select transistor SGT is commonly connected to the source line SL.

That is, the string unit SU is a set including the memory strings MST connected to different bit lines BL0 to BLk and connected to the same select gate line SGD. Each block BLK is a set including the plurality of string units SU0 to SU3, which commonly share the word lines WL. The memory cell array 2 is a set including the plurality of blocks BLK, which commonly share the bit lines BL0 to BLk.

A group of the memory cells MT sharing the word line WL is also referred to as a “memory cell group MCG”. Here, the memory cell group MCG is a minimum unit of a set including the memory cells MT capable of collectively applying a predetermined voltage (for example, a write voltage or a read voltage) via the word line WL.

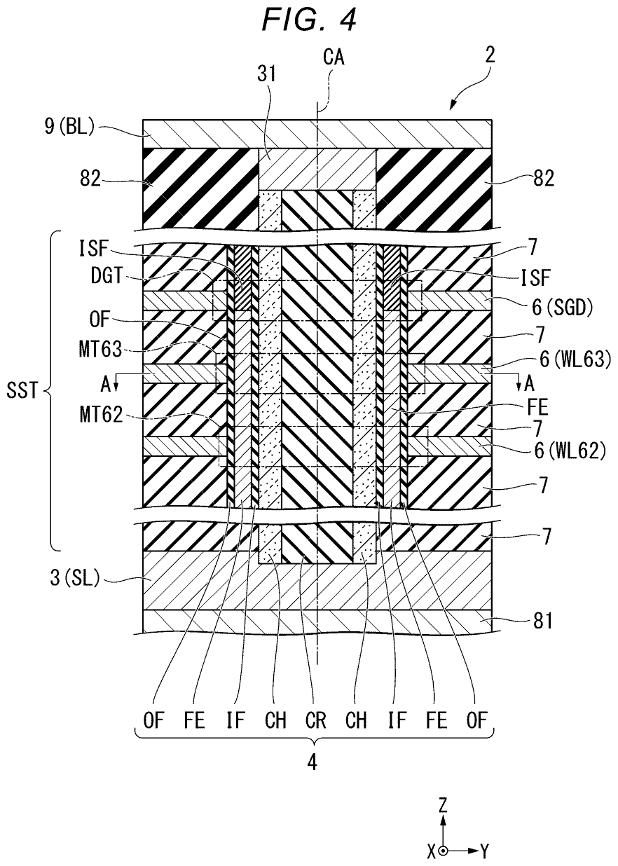

Next, a cross-sectional configuration of the memory cell array 2 will be described with reference to FIG. 4. FIG. 4 is a sectional view illustrating a partial configuration of the memory cell array 2.

In the semiconductor memory device 1, a conductive layer 3 is disposed on the +Z side of the substrate SUB with the interlayer insulating film 81 interposed therebetween. The conductive layer 3 may be formed with a material of which a main component is a semiconductor having impurities (for example, silicon) or a material of which a main component is a conductor (for example, metal such as tungsten). The conductive layer 3 extends in a plate shape in XY directions and functions as the source line SL (see FIG. 1). The plurality of columnar bodies 4 are disposed on the +Z side of the conductive layer 3. In FIG. 4, for example, one of the plurality of columnar bodies 4 is illustrated. The plurality of columnar bodies 4 are arranged to be spaced in the XY directions. Each columnar body 4 extends in the Z direction inside the stacked body SST (see FIG. 1).

Each columnar body 4 has a generally columnar shape with a central axis CA extending in the Z direction and has, for example, a substantially cylindrical shape. Each columnar body 4 may have a tapered shape in which a diameter thereof at the −Z side end is smaller than a diameter thereof at the +Z side end. The columnar body 4 may also have a bowing shape in which the diameter at the −Z side end is smaller than the diameter at the +Z side end, and the diameter expands at a predetermined Z position between the +Z and −Z side ends. In FIG. 4, for simplification, a substantially cylindrical shape is illustrated as an example of the shape of each columnar body 4.

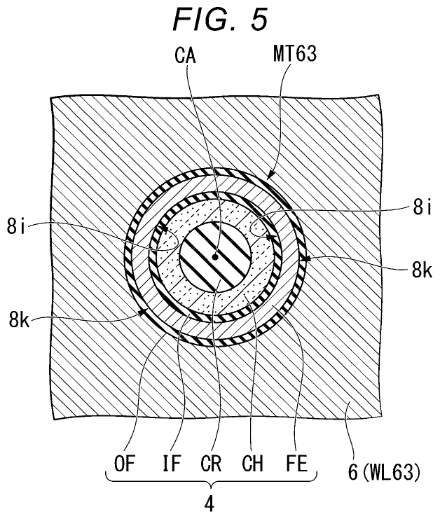

As illustrated in FIGS. 4 and 5, the columnar body 4 includes a core member CR, a semiconductor film (electrode film) CH, an inner insulating film IF, a ferroelectric film FE, and an outer insulating film (first insulating film) OF sequentially from the central axis CA side. FIG. 5 is an enlarged sectional view illustrating a configuration of the memory cell MT in the XY directions and is an enlarged view illustrating an XY cross-section along a line A-A of FIG. 4.

The core member CR has a substantially cylindrical shape formed near the central axis CA of the columnar body 4 and extending along the central axis CA of the columnar body 4. The core member CR may be formed with a material of which a main component is an insulator (for example, semiconductor oxides such as silicon oxide).

The semiconductor film CH has a substantially cylindrical shape surrounding the core member CR from outside and extending along the central axis CA of the columnar body 4. The semiconductor film CH may be formed with a material of which a main component is a semiconductor substantially having no impurities (for example, polysilicon).

The inner insulating film IF may be formed with a material of which a main component is an insulator (for example, semiconductor oxides such as silicon oxide). In the present embodiment, the inner insulating film IF is provided. The inner insulating film IF may be omitted without causing any problem.

The outer insulating film (first insulating film) OF may be formed with a material of which a main component is an insulator (for example, semiconductor oxides such as silicon oxide). For example, the outer insulating film (first insulating film) OF is a silicon oxide film.

The ferroelectric film FE is disposed with the inner insulating film IF and the outer insulating film OF on a side surface of each columnar body 4 in the stacked body SST. The ferroelectric film FE is disposed extending in the Z direction in the stacked body SST and surrounding the semiconductor film CH from outside via the inner insulating film IF. The ferroelectric film FE is disposed in a substantially cylindrical shape with the central axis CA inside. An inner surface 8i of the ferroelectric film FE faces the central axis CA. An outer surface 8k of the ferroelectric film FE faces a side opposite to the central axis CA.

The ferroelectric film FE may be formed with a material of which a main component is ferroelectric. The ferroelectric film FE may be formed with, for example, a material of which a main component is hafnium oxide (HfO). The ferroelectric film FE may be formed with a material that further includes at least one element selected from the group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

The semiconductor film CH of the columnar body 4 is connected to the conductive layer 3 functioning as the source line SL on the −Z side of the semiconductor film CH relative to the stacked body SST. The semiconductor film CH of the columnar body 4 is connected to a conductive layer 9 functioning as the bit line BL via the contact plug 31 on the +Z side of the semiconductor film CH relative to the stacked body SST. One end of the semiconductor film (electrode film) CH is connected to the bit line BL, and the other end is connected to the source line SL.

That is, the semiconductor film CH includes a channel region (active region) in the memory string MST.

In the stacked body SST, conductive layers (electrode layers) 6 and the insulating layers 7 are alternately stacked. Each conductive layer 6 extends in a plate shape in the XY directions. Each conductive layer 6 may be formed with a material of which a main component is a conductor (for example, metal such as tungsten or molybdenum). Each insulating layer 7 extends in a plate shape in the XY directions. Each insulating layer 7 may be formed with a material of which a main component is an insulator (for example, semiconductor oxides such as silicon oxide).

In the stacked body SST, among the plurality of conductive layers 6 arranged to be spaced in the Z direction, the conductive layer 6 closest to the −Z side functions as the select gate line SGS, the conductive layer 6 closest to the +Z side functions as the select gate line SGD, and the rest of the conductive layers 6 function as the word lines WL0 to WL63. In FIG. 4, the conductive layer 6 functioning as the select gate line SGD and the conductive layers 6 functioning as the word lines WL62 and WL63 are illustrated as an example.

The select transistor SGT (see FIG. 3) is formed at a position at which the conductive layer 6 of the select gate line SGS intersects the semiconductor film CH. The outer insulating film OF interposed between the conductive layer 6 of the select gate line SGS and the semiconductor film CH functions as a gate insulating film.

The memory cell MT0 (see FIG. 3) is formed at a position at which the conductive layer 6 of the word line WL0 intersects the semiconductor film CH. The memory cell MT1 is formed at a position at which the conductive layer 6 of the word line WL1 intersects the semiconductor film CH. The memory cell MT2 is formed at a position at which the conductive layer 6 of the word line WL2 intersects the semiconductor film CH. The memory cell MT3 is formed at a position at which the conductive layer 6 of the word line WL3 intersects the semiconductor film CH. The memory cell MT4 is formed at a position at which the conductive layer 6 of the word line WL4 intersects the semiconductor film CH.

Hereinafter, at positions at which the conductive layers 6 of the word lines WL5 to WL63 sequentially intersect the semiconductor film CH, the memory cells MT5 to MT63 (see FIG. 3) are sequentially formed. In the memory cells MT0 to MT63, the outer insulating film OF interposed between each of the conductive layers 6 and the semiconductor films CH functions as a gate insulating film.

In the present embodiment, in the stacked body SST, the ferroelectric film FE is provided from a position corresponding to the conductive layer 6 of the select gate line SGS to a position corresponding to the conductive layer 6 of the word line WL63. Conversely, at a position corresponding to the select gate line SGD, the ferroelectric film FE is not provided and a non-ferroelectric insulating film (second insulating film) ISF that is not ferroelectric is formed instead of the ferroelectric film FE. While the ferroelectric film FE is an insulator in which polarization is maintained even when the electric field is applied for polarization and then becomes zero, the second insulating film ISF used here is an insulating film that is not polarized even when an electric field is applied. As an example, the second insulating film ISF includes a silicon oxide film.

A film thickness of the second insulating film ISF is substantially the same as that of the ferroelectric film FE. A configuration in which the second insulating film ISF is provided with the inner insulating film IF inside and the outer insulating film (first insulating film) OF outside is the same as the configuration in which the ferroelectric film FE is disposed. In the example illustrated in FIG. 4, the second insulating film ISF is provided from a position of the conductive layer 6 to be the select gate line SGD to the insulating layer 7 located in the +Z direction (upward). Similarly to the ferroelectric film FE, the second insulating film ISF has a substantially cylindrical shape along the central axis CA of the columnar body 4.

At a position at which the conductive layer 6 of the select gate line SGD intersects the semiconductor film CH, the select transistor DGT (see FIGS. 3 and 4) is formed. In the select transistor DGT, the outer insulating film (first insulating film) OF, the second insulating film ISF, and the inner insulating film IF that are interposed between the conductive layer 6 of the select gate line SGD and the semiconductor film CH function as gate insulating films.

A voltage V is applied to the ferroelectric film FE in a direction from the semiconductor film CH to the conductive layer 6 or a direction from the conductive layer 6 to the semiconductor film CH. Polarization charge is generated on the inner surface 8i and the outer surface 8k of the ferroelectric film FE. In other words, an application direction of the voltage is a direction along an XY plane and is a radial direction from the central axis CA within the substantial XY plane or the opposite direction to the radial direction. On a YZ cross-section passing the central axis CA, as illustrated in FIG. 4, the application direction corresponds to a direction along the Y direction.

### Ferroelectricity and Memory Function of Ferroelectric Film FE

Each ferroelectric film FE may be a single crystal form or a polycrystalline form. In the ferroelectric film FE, crystals inducing ferroelectricity and crystals inducing antiferroelectricity may coexist. For example, the ferroelectric film FE contains a plurality of crystals that are each orthorhombic or rhombohedral. Each crystal has three crystallographic axes (a-axis, b-axis, and c-axis). Among the three crystallographic axes, the b-axis is shorter than the a-axis. The c-axis is shorter than the a-axis and longer than the b-axis. The c-axis functions as a polarization axis. An orthorhombic or rhombohedral oxide film may be applied to the ferroelectric film FE.

Whether crystals induce ferroelectricity or antiferroelectricity depends on an application direction of the voltage V to the ferroelectric film FE and an orientation direction of the crystals in the ferroelectric film FE. When the crystals are oriented such that the c-axis intersects the application direction of the voltage V, the crystals tend to induce antiferroelectricity. When the crystals are oriented such that the c-axis is in the application direction of the voltage V (for example, the c-axis is parallel to the application direction of the voltage V), the crystals tend to induce ferroelectricity.

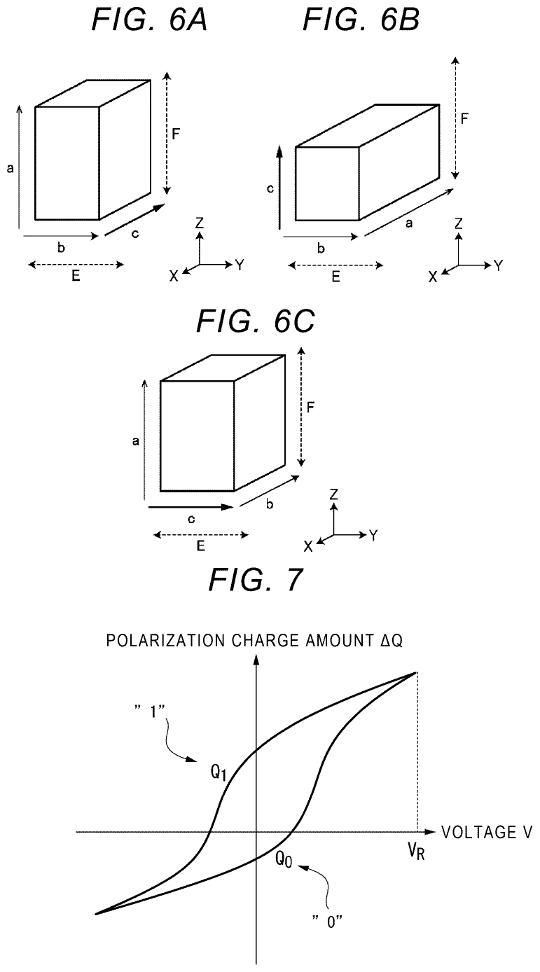

For example, in the orientation direction of the crystals illustrated in FIG. 6A, the c-axis intersects the application direction of the voltage V.

FIGS. 6A to 6C are perspective views illustrating a direction of a crystal axis of the ferroelectric film FE. Here, the crystals induce antiferroelectricity. The a-axis is substantially parallel to the stacking direction (Z direction), the b-axis is substantially parallel to the application direction of the voltage V in a planar direction (XY directions), and the c-axis is substantially perpendicular to the application direction of the voltage V in a planar direction (XY directions). As one example, on the YZ cross-section passing the central axis CA (see FIG. 4), the a-axis is substantially parallel to the Z direction, the b-axis is substantially parallel to the Y direction, and the c-axis is substantially parallel to the X direction.

In the orientation direction of the crystals illustrated in FIG. 6B, the c-axis intersects the application direction of the voltage V. Here, the crystals induce antiferroelectricity. The c-axis is substantially parallel to the stacking direction (Z direction) and substantially perpendicular to the application direction of the voltage V. The b-axis is substantially parallel to the application direction of the voltage V in the planar direction (XY directions), and the a-axis is substantially perpendicular to the application direction of the voltage V in the planar direction (XY directions). On the YZ cross-section passing the central axis CA (see FIG. 4), the a-axis is substantially parallel to the X direction, the b-axis is substantially parallel to the Y direction, and the c-axis is substantially parallel to the Z direction.

Meanwhile, in the orientation direction of the crystals illustrated in FIG. 6C, the c-axis is in the application direction of the voltage V. Here, the crystals induce ferroelectricity. The a-axis is approximately parallel to the stacking direction (Z direction), the c-axis is substantially parallel to the application direction of the voltage V in the planar direction (XY directions), and the b-axis is substantially perpendicular to the application direction of the voltage V in the planar direction (XY directions). On the YZ cross-section passing the central axis CA (see FIG. 4), the a-axis is substantially parallel to the Z direction, the b-axis is substantially parallel to the X direction, and the c-axis is substantially parallel to the Y direction.

In the ferroelectric film FE of each memory cell MT, when a proportion of crystals inducing antiferroelectricity is high, spontaneous polarization is less likely to occur and it is difficult to guarantee a sufficient amount of polarization charge. Therefore, it is difficult to write information into the memory cell MT. When a proportion of crystals inducing ferroelectricity is high, spontaneous polarization is more likely to occur and it is easy to guarantee the amount of polarization charge. Therefore, it is easy to write information into the memory cell MT. Accordingly, it is preferable to form the ferroelectric film FE such that crystal orientation is favorable, or to align the crystal orientations by thermal processing after film formation such that spontaneous polarization is generated more easily in a target direction.

In each memory cell MT, the conductive layer 6 functions as a gate electrode, the semiconductor film CH functions as a channel region, and the ferroelectric film FE functions as a two-terminal element capable of generating polarization charge between each of contact interfaces of the ferroelectric film FE and the conductive layer 6 and a contact interface of the ferroelectric film FE and the semiconductor film CH.

For example, when an electric field in which the conductive layer 6 becomes positive for the semiconductor film CH (E>0) is applied to the ferroelectric film FE, a write operation, in which the threshold voltage (Vth) shifts in the negative direction, of the memory cell MT is executed. A value of “1” may be written on the memory cell MT. When the memory cell MT is easily spontaneously polarized, the memory cell MT can store the value of “1”. For example, when the memory cell MT induces ferroelectricity as indicated by a solid line in FIG. 7, the ferroelectric film FE maintains a positive polarization charge amount ΔQ=Q1 (>0) near the side surface 8i in a state that the voltage V applied to the ferroelectric film FE is released. The polarization charge amount ΔQ=Q1 corresponds to a bit value of “1”.

When an electric field in which the conductive layer 6 becomes negative for the semiconductor film CH (E<0) is applied to the ferroelectric film FE, an erase operation, in which the threshold voltage (Vth), shifts in the positive direction, of the memory cell MT is executed. The value of “1” may be erased from the memory cell MT. When the memory cell MT is easily spontaneously polarized, the memory cell MT can store a value of “0”. For example, when the memory cell MT induces ferroelectricity as indicated by the solid line in FIG. 7, the ferroelectric film FE maintains a negative polarization charge amount ΔQ=Q0 (<0) near the side surface 8 i in a state that the voltage V applied to the ferroelectric film FE is released. The polarization charge amount ΔQ=Q0 corresponds to a bit value of “0”.

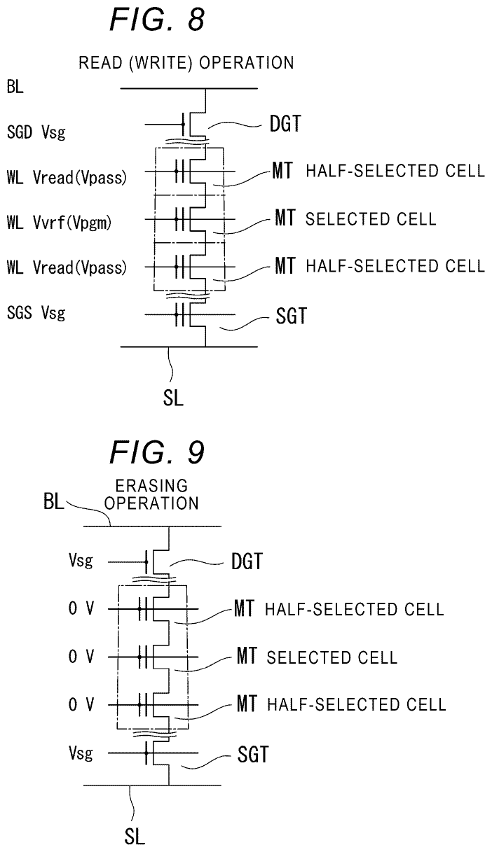

FIG. 8 is an example of a circuit diagram illustrating a read operation and a write operation in the memory string MST in which the memory cells MT are connected in series. FIG. 9 is an example of a circuit diagram illustrating an erase operation in the memory string MST in which the memory cells MT are connected in series.

In the read operation in FIG. 8, a read voltage Vvrf is applied to a selected cell and a voltage Vread for turning on a transistor is applied to an adjacent half-selected cell. In the write operation in FIG. 8, a voltage Vpgm is applied to a selected cell and a pass potential Vpass for turning on a transistor is applied to an adjacent cell. In FIG. 9, for a selected cell and other cells adjacent to the selected cell, an erasing voltage Vsg is applied as a potential of 0 V to the select gate line SGD and the select gate line SGS.

In either FIG. 8 or 9, the voltage Vsg is applied to the select gate line SGD. However, when the select transistor DGT illustrated in FIGS. 8 and 9 is also a transistor provided with the ferroelectric film FE, the following problem may occur.

When the voltage Vvrf applied to the selected cell is close to the voltage of the select gate line SGD applied to the select transistor DGT (Vsg), Vth modulation (threshold voltage modulation) may occur in the select transistor DGT due to writing by polarization reversal of the ferroelectric film FE or charge trapping. When the threshold voltage modulation occurs, an on-current of the select transistor DGT may vary. Therefore, erroneous reading may occur. Since parasitic resistance of a channel in the select transistor DGT changes, variation in speed performance may be considered.

Conversely, in the first embodiment, as illustrated in FIG. 4, only the select transistor DGT includes the second insulating film ISF that is not a ferroelectric film instead of the ferroelectric film FE. Accordingly, an electric field across the first insulating film OF and the second insulating film ISF to be the gate insulating film can be reduced, thereby preventing threshold voltage modulation (Vth modulation) due to polarization reversal or charge trapping. Therefore, it is possible to implement the select transistor DGT in which change in the threshold voltage is prevented. Accordingly, it is possible to provide the semiconductor memory device 1 in which erroneous reading is prevented and variation in speed performance is small.

### Second Embodiment

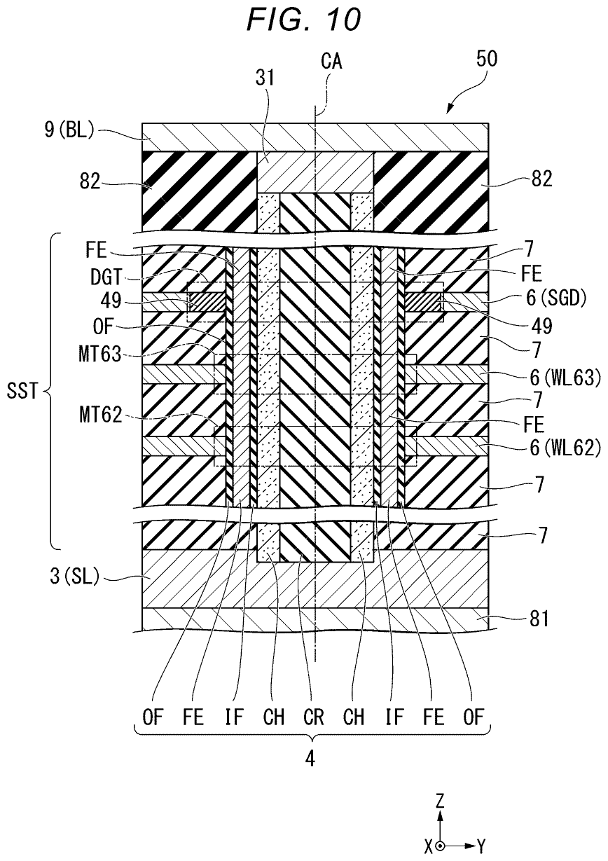

FIG. 10 is a partial sectional view illustrating a configuration of a memory cell array 50 provided in a semiconductor memory device according to a second embodiment. The memory cell array 50 illustrated in FIG. 10 is a partial cross-section viewed in the same direction as that of the memory cell array 2 illustrated in FIG. 4. In the memory cell array 50 according to the second embodiment, the same reference signs are given to the same components as those of the memory cell array 2 according to the first embodiment, and description of the same components will be simplified or omitted.

In the memory cell array 50 according to the second embodiment, a configuration in which the conductive layers 6 and the insulating layers 7 are stacked to form the stacked body SST and the select gate lines SGD, the word lines WL, and the select gate lines SGS are provided is similar to that of the first embodiment.

In the memory cell array 2 according to the first embodiment, the second insulating film ISF that is not ferroelectric is provided instead of the ferroelectric film FE between the semiconductor film CH and the conductive layer 6 of the select gate line SGD. Conversely, in the memory cell array 50 according to the second embodiment, the ferroelectric film FE is formed until a position at which the second insulating film ISF is provided in the first embodiment. In the second embodiment, the ferroelectric film FE is formed until the position of the select transistor DGT located in an uppermost portion of the stacked body SST.

The inner insulating film IF is formed between the ferroelectric film FE formed at the position of the select transistor DGT and the semiconductor film CH. The ferroelectric film FE formed at the position of the select transistor DGT has a semicylindrical shape similar to the ferroelectric films FE formed at another location. The outer insulating film OF is formed outside the ferroelectric film FE formed at the position of the select transistor DGT.

In the first embodiment, the conductive layer 6 for configuring the select gate line SGD outside the outer insulating film OF is formed in contact with the outer insulating film OF. In contrast, in the second embodiment, an annular third insulating film 49 is formed inside the conductive layer 6 for configuring the select gate line SGD to surround the cylindrical outer insulating film OF outside the outer insulating film (first insulating film) OF. The conductive layer 6 for configuring the select gate line SGD is disposed outside the third insulating film 49. The third insulating film 49 includes, for example, a silicon oxide film.

In the second embodiment, as illustrated in FIG. 10, only the select transistor DGT includes the third insulating film 49. The outer insulating film OF is provided inside the third insulating film 49. Thus, when an electric field is applied from the conductive layer 6, the conductive layer 6 applies an electric field to the ferroelectric film FE via the third insulating film 49 and the outer insulating layer OF. That is, in such a configuration, it is more difficult for an electric field to be applied to the ferroelectric film FE compared to a configuration not provided with the third insulating film 49.

Therefore, by reducing an electric field applied entirely to the third insulating film 49 and the outer insulating film (first insulating film) OF to be the gate insulating films, a configuration less susceptible to threshold voltage modulation due to polarization reversal and charge trapping can be implemented. Therefore, the select transistor DGT in which the threshold voltage variation is prevented can be implemented. Accordingly, it is possible to provide the semiconductor memory device including the memory cell array 50 in which erroneous reading is prevented and variation in speed performance is small.

As illustrated in FIG. 10, when the third insulating film 49 is disposed while the ferroelectric film FE is provided such that the electric field applied to the ferroelectric film FE is reduced, a thickness of the third insulating film 49 (in the Y direction) is preferably at least 1.3 times thicker than a thickness of the outer insulating film OF in the same direction.

### Manufacturing Method According to First Embodiment

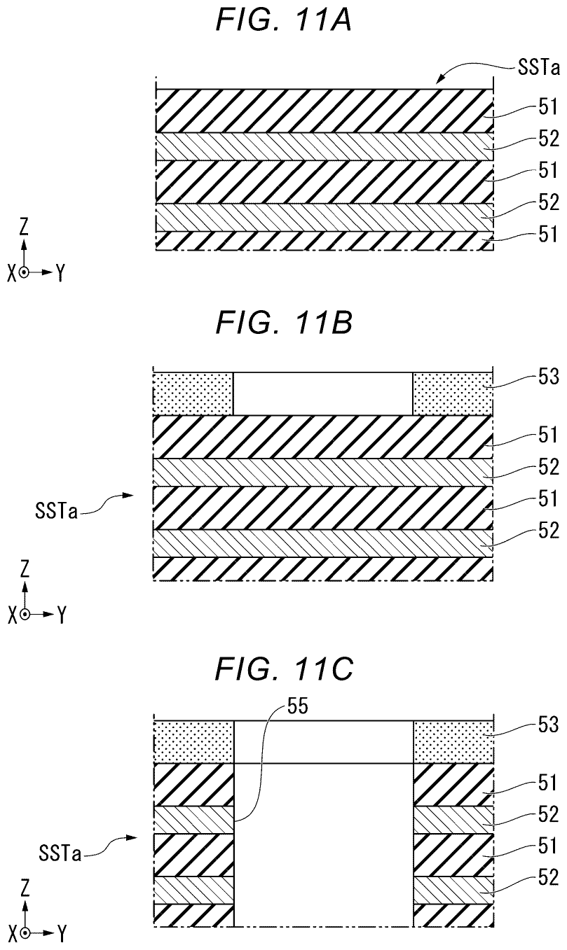

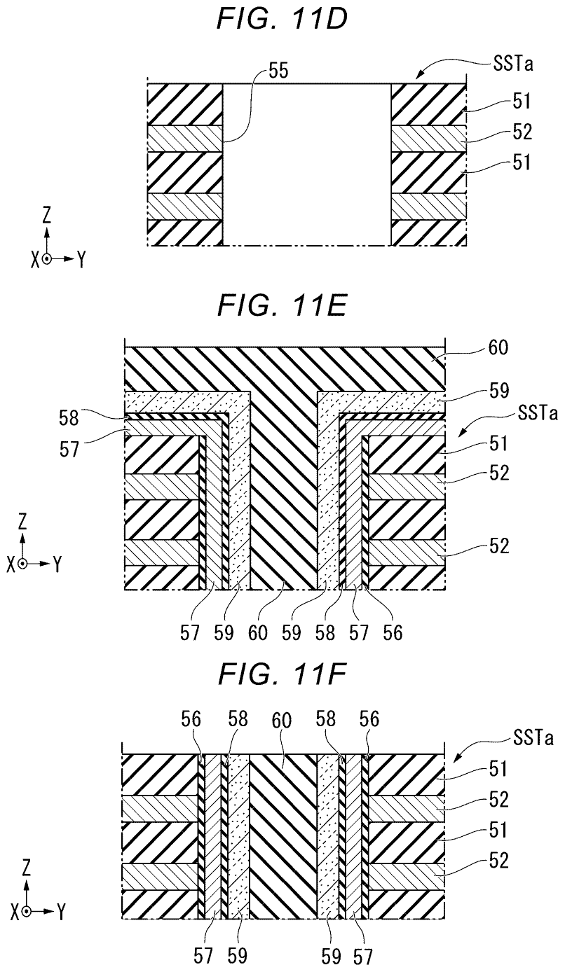

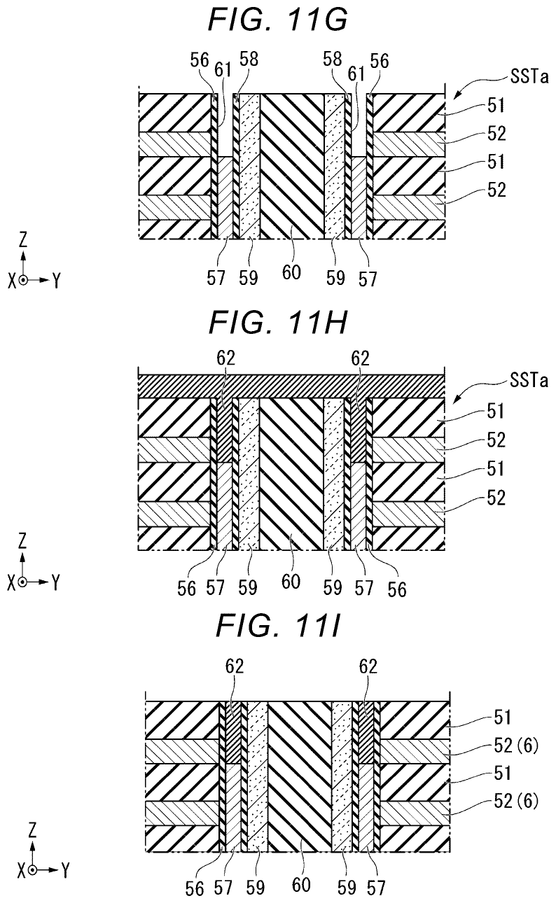

Next, a method of manufacturing the semiconductor memory device 1 will be described with reference to FIGS. 11A to 11I. FIGS. 11A to 11I are sectional views illustrating an example of a method of manufacturing the semiconductor memory device 1.

In advance of a process illustrated in FIG. 11A, transistors are formed on the substrate SUB (see FIG. 1), contact plugs, wiring films, via plugs, and the like are formed on the substrate SUB, and interlayer insulating films are formed around the components. Accordingly, the peripheral circuit 100 (see FIG. 2) is formed. Subsequently, the interlayer insulating film 81 (see FIG. 1) is deposited on the +Z side of the substrate SUB. The interlayer insulating film 81 may be formed with a material of which a main component is an insulator (for example, semiconductor oxides such as silicon oxide). The conductive layer 3 (see FIG. 4) is deposited on the +Z side of the interlayer insulating film 81. The conductive layer 3 may be formed with a material of which a main component is a semiconductor having impurities (for example, silicon) or a material of which a main component is a conductor (for example, metal such as tungsten).

In a process illustrated in FIG. 11A, a first insulating layer 51 and a second insulating layer (sacrifice layer) 52 are alternately deposited on the +Z side of the conductive layer 3 a plurality of times to form a stacked body SSTa. The first insulating layer 51 may be formed with a material of which a main component is an insulator such as silicon oxide (SiO). The second insulating layer 52 may be formed with a material of which a main component is an insulator such as silicon nitride (SiN). The first insulating layer 51 and the second insulating layer 52 may be deposited to approximately the same film thickness. In FIG. 11A and subsequent drawings, the first insulating layer 51 is illustrated to be slightly thicker than the second insulating layer 52 for clarity.

In a process illustrated in FIG. 11B, a resist pattern 53 opened at a formation position of a memory hole is formed on the uppermost insulating layer 51 of the stacked body SSTa. As illustrated in FIG. 11C, anisotropic etching such as reactive ion etching (RIE) is performed using the resist pattern as a mask, thereby forming memory holes 55 penetrating the stacked body SSTa and reaching the conductive layer 3.

In a process illustrated in FIG. 11D, the resist pattern 53 is peeled off. In a process illustrated in FIG. 11E, an insulating film 56, a ferroelectric film 57, an insulating film 58, a semiconductor film 59, and a core film 60 are sequentially formed on the stacked body SSTa including the memory holes 55. By such a film forming process, as illustrated in FIG. 11E, inside of the memory holes 55 is filled with the insulating film 56, the ferroelectric film 57, the insulating film 58, the semiconductor film 59, and the core film 60. The memory holes 55 are filled with the films since the core film 60 is formed with a sufficiently greater thickness than the insulating film 56, the ferroelectric film 57, the insulating film 58, and the semiconductor film 59.

The core film 60 may be formed with an insulator such as silicon oxide. The semiconductor film 59 may be formed with a material of which a main component is a semiconductor substantially having no impurities (for example, polysilicon). The insulating film 58 may be formed with a material including an insulator that is not polarized even when an electric field is applied (for example, silicon oxide). The ferroelectric film 57 may be formed with a material of which a main component is a ferroelectric that is polarized when an electric field is applied (for example, hafnium oxide). The insulating film 56 may be formed with a material including an insulator that is not polarized when an electric field is applied (for example, silicon oxide).

A material configuring the ferroelectric film 57 may contain at least one of the following elements in addition to hafnium.

The material contains at least one element selected from the group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

The insulating film 56, the ferroelectric film 57, the insulating film 58, the semiconductor film 59, and the core film 60 are also deposited on an upper surface side of the stacked body SSTa. In a process illustrated in FIG. 11F, the films deposited on the upper surface side of the stacked body SSTa are removed by chemical mechanical polishing (CMP). CMP is executed until the uppermost insulating layer 51 of the stacked body SSTa is exposed.

In the process illustrated in FIG. 11F, a structure in which inside of the memory hole 55 is filled with the insulating film 56, the ferroelectric film 57, the insulating film 58, the semiconductor film 59, and the core film 60 is obtained. When the memory hole 55 is, for example, a circular hole, the columnar core film 60 is formed at the center, and the semiconductor film 59, the insulating film 58, the ferroelectric film 57, and the insulating film 56 are formed in cylindrical shapes with specified film thicknesses around the core film 60.

Subsequently, in a process illustrated in FIG. 11G, the ferroelectric film 57 extending inside the uppermost first insulating layer 51 of the stacked body SSTa and inside the second insulating layer (sacrifice layer) 52 below the first insulating layer 51 is removed by an etching process using an etchant such as phosphoric acid. A recess 61 that is annular in a plan view is formed inside the memory hole 55 to reach inside of the uppermost first insulating layer 51 and inside of the second insulating layer 52 below the uppermost first insulating layer 51.

After the recess 61 is formed, an insulating film 62 is formed to fill the recess 61 in a process illustrated in FIG. 11H. The insulating film 62 is also deposited on the stacked body SSTa. In a process illustrated in FIG. 11I, the insulating film 62 on the stacked body SSTa is removed by CMP. Therefore, a structure illustrated in FIG. 11I is obtained.

Thereafter, a conductive layer 6 illustrated in FIG. 4 is formed by a replacement process of replacing the second insulating layer 52 formed in the stacked body SSTa with a metal layer such as tungsten. When the interlayer insulating layer, the contact plug 31, and the bit line BL are formed, a structure equivalent to that illustrated in FIG. 4 is obtained. In FIG. 11I, since the metal layer (conductive layer) 6 is formed at the position of the second insulating layer 52 after the replacement process, a parenthesized reference sign (6) next to a reference sign 52 indicates that the second insulating layer (sacrifice layer) 52 is replaced by the conductive layer 6.

### Method of Manufacturing Structure Similar to First Embodiment

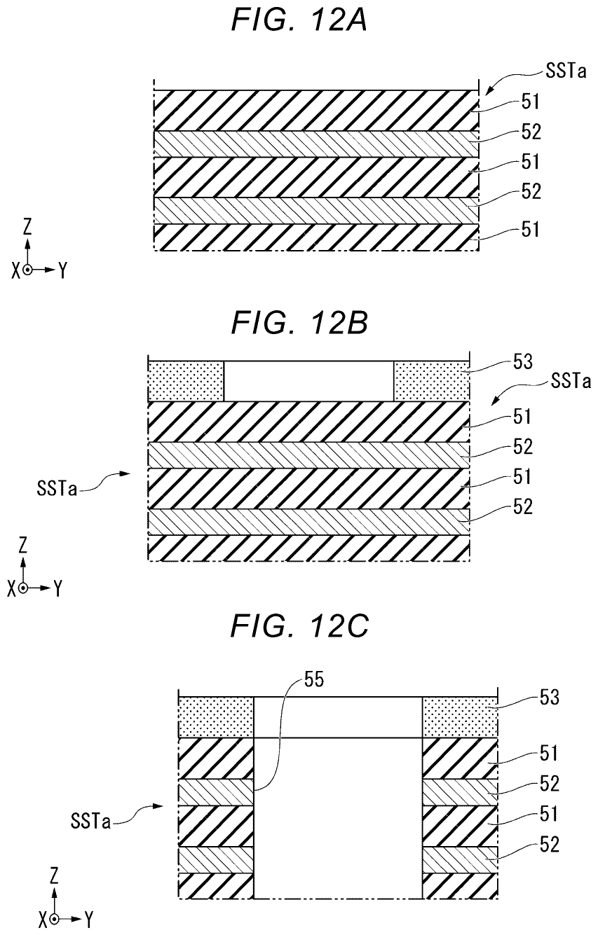

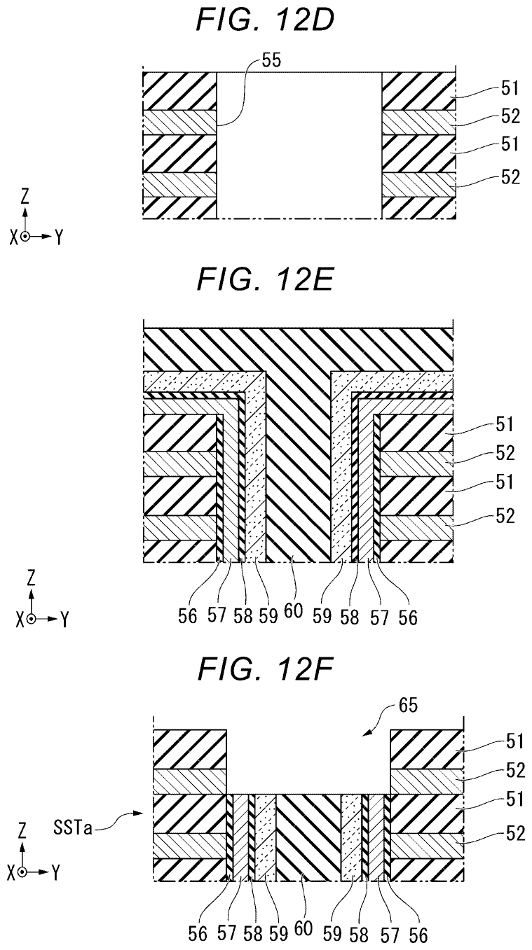

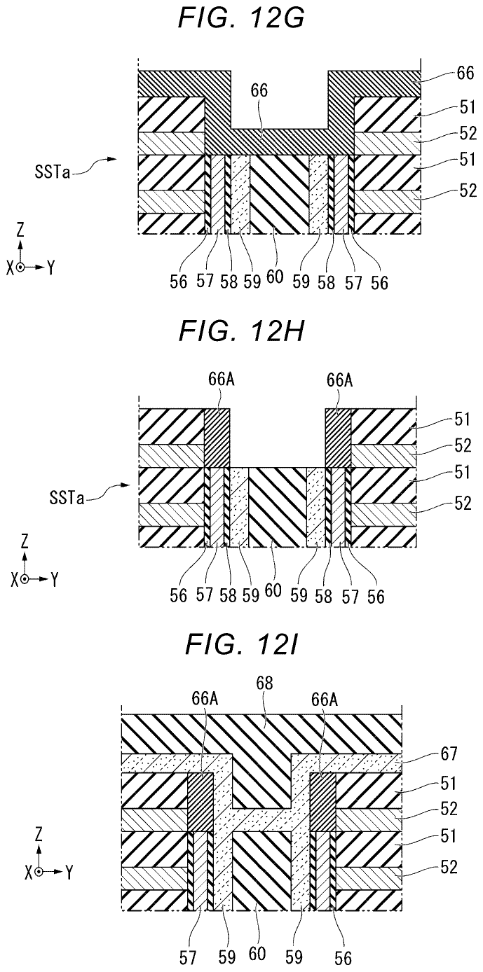

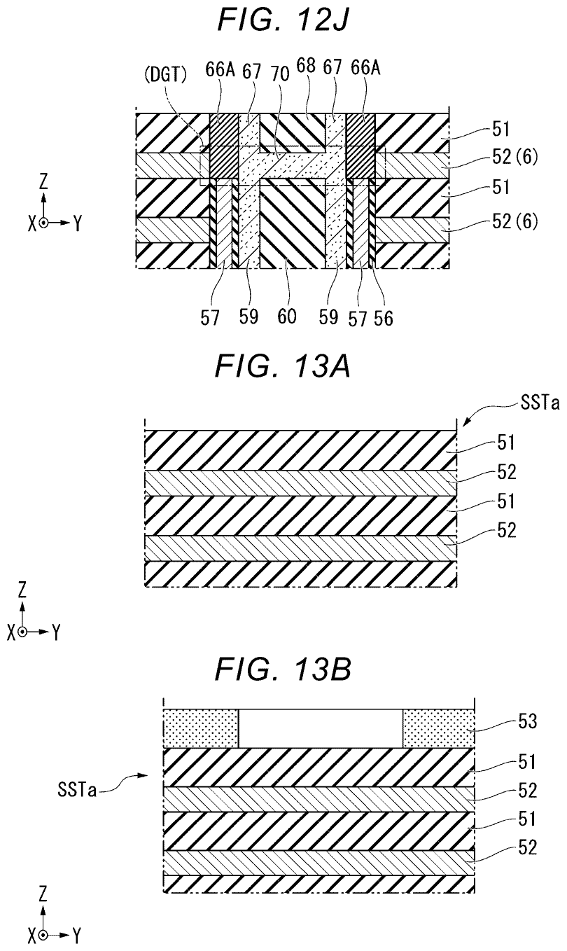

FIGS. 12A to 12J illustrate an example of a manufacturing method related to a structure similar to the first embodiment. FIGS. 12A to 12J are sectional views illustrating the example of the manufacturing method related to the structure similar to the semiconductor memory device 1 according to the first embodiment.

Before a process illustrated in FIG. 12A, processes of forming the peripheral circuit 100 on the substrate SUB and depositing the interlayer insulating film 81 and the conductive layer 3 are performed similarly to the above-described manufacturing method. The processes illustrated in FIGS. 12A to 12E are the same as the processes illustrated in FIGS. 11A to 11E in the above-described manufacturing method.

As in the structure illustrated in FIG. 11A above, FIG. 12A illustrates a state in which the first insulating layers 51 and the second insulating layers 52 are alternately deposited a plurality of times to form the stacked body SSTa.

As in the process illustrated in FIG. 11B above, FIG. 12B illustrates a state in which the resist pattern 53 is formed on the uppermost first insulating layer 51 of the stacked body SSTa. As in the process illustrated in the FIG. 11C above, FIG. 12C illustrates a state in which the memory hole 55 is formed in the stacked body SSTa. As in the process illustrated in the FIG. 11D above, FIG. 12D illustrates a state in which the resist pattern 53 is peeled off.

As in the process shown in the FIG. 11E above, FIG. 12E illustrates a state in which inside of the memory hole 55 is filled with the insulating film 56, the ferroelectric film 57, the insulating film 58, the semiconductor film 59, and the core film 60.

In the manufacturing method of the example, in a process illustrated in FIG. 12F, an etching process using a diluted hydrofluoric acid (DHF) is executed. By the etching process, the core film 60 deposited on the upper surface side of the stacked body SSTa and the uppermost first insulating layer 51 are removed. The core film 60 inside the memory hole 55 is also removed to the depth of the uppermost second insulating layer 52. Subsequently, the semiconductor film 59 is removed to the depths of the uppermost first insulating layer 51 and the uppermost second insulating layer 52 using a strong alkaline solution. Subsequently, the ferroelectric film 57 is removed to the depths of the uppermost first insulating layer 51 and the uppermost second insulating layer 52 using a phosphoric acid solution. The insulating film 58 is removed using a diluted hydrofluoric acid (DHF).

By the above processes, as illustrated in FIG. 12F, a recess 65 reaching the depths of the uppermost first insulating layer 51 and the uppermost second insulating layer 52 is formed inside the insulating film 58.

In a process illustrated in FIG. 12G, an insulating film 66 is formed to cover the upper surface of the stacked body SSTa and inner and bottom surfaces of the recess 65. A material used to form the insulating film 66 is an insulating material such as silicon oxide that is not polarized.

In a process illustrated in FIG. 12H, anisotropic etching such as RIE is executed to remove the insulating film 66 on the upper surface of the stacked body SSTa and remove the insulating film 66 formed on the bottom surface of the recess 65. By such a process, only a portion of the insulating film 66 formed on the inner side surface of the recess 65 remains to become a third insulating film 66A.

In a process illustrated in FIG. 12I, a semiconductor film 67 and a core film 68 are formed again. Accordingly, a structure illustrated in FIG. 12I is obtained.

Subsequently, in a process illustrated in FIG. 12J, chemical mechanical polishing (CMP) is executed to remove films deposited on the upper surface of the stacked body SSTa. By such a process, a structure illustrated in FIG. 12J is obtained.

Even in the structure illustrated in FIG. 12J, a replacement process of replacing the second insulating layer 52 formed in the stacked body SSTa with a metal layer such as tungsten and forming the conductive layer (electrode layer) 6 illustrated in FIG. 4 is executed. When the interlayer insulating layer is formed, the contact plug 31 is formed, and the bit line BL is formed, a structure similar to the structure illustrated in FIG. 4 can be obtained.

In the structure illustrated in FIG. 12J, since the conductive layer (metal layer) 6 is formed at the position of the second insulating layer 52 by the replacement process and the select transistor DGT is formed, a parenthesized reference sign (6) is written next to a reference sign 52 and a parenthesized reference sign (DGT) is written at a position at which the select transistor DGT is to be formed.

When the conductive layer 6 is formed in the structure illustrated in FIG. 12J by the replacement process, the semiconductor films (electrode films) 59 and 67 form a cylindrical shape and extend in the stacking direction inside the stacked body SSTa, and the select transistor DGT is provided with the third insulating film 66A and the ferroelectric film FE around the semiconductor films 59 and 67. The select transistor DGT has a structure including a node 70 in which a part of the semiconductor film 67 extends inside the semiconductor films 59 and 67. In the cross-section illustrated in FIG. 12J, the semiconductor films 59 and 67 and the node 70 are disposed in an H shape in the portion of the select transistor DGT.

When the conductive layer 6 is formed in the structure illustrated in FIG. 12J and the select transistor DGT is formed, the third insulating film 66A that is not polarized is formed in the select transistor DGT instead of the ferroelectric film 57. Therefore, in the select transistor DGT, threshold voltage modulation (Vth modulation) due to polarization reversal and charge trapping can be prevented. Therefore, it is possible to implement the select transistor DGT in which change in the threshold voltage is prevented. Accordingly, it is possible to provide the semiconductor memory device 1 in which erroneous reading is prevented and variation in speed performance is small.

### First Example of Manufacturing Method According to Second Embodiment

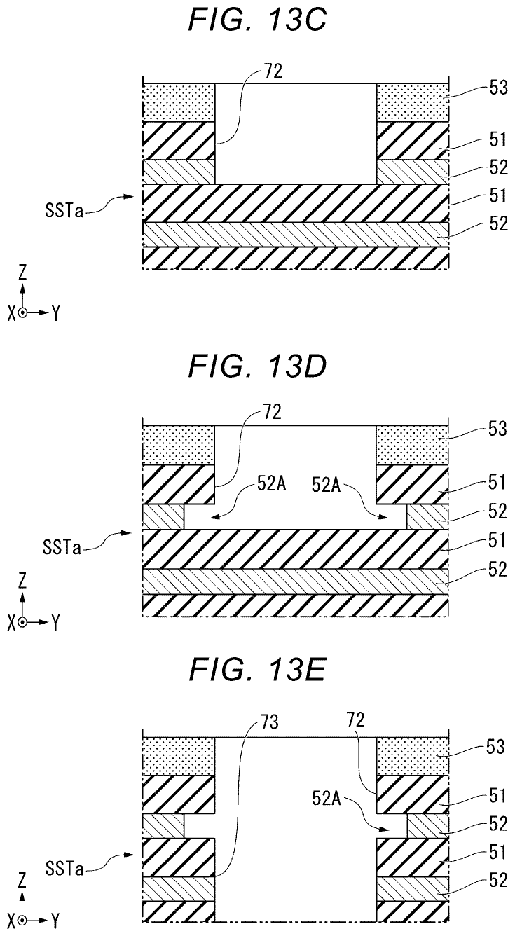

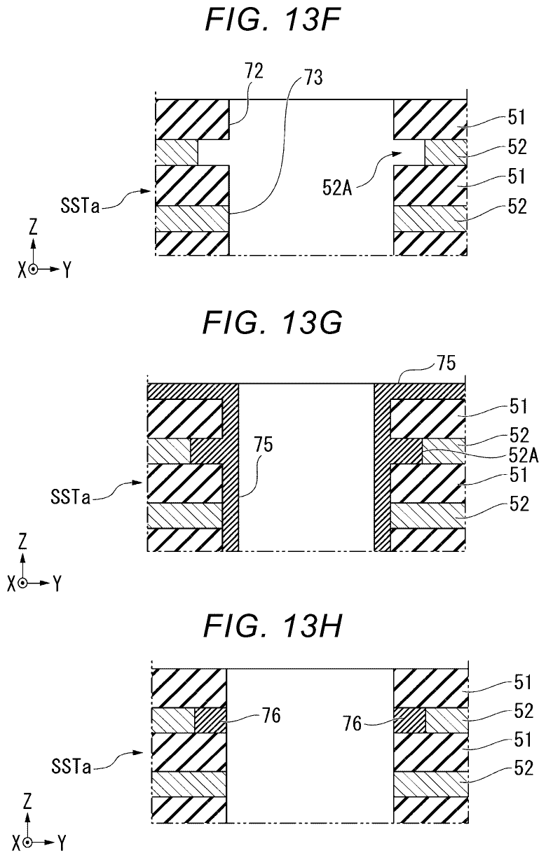

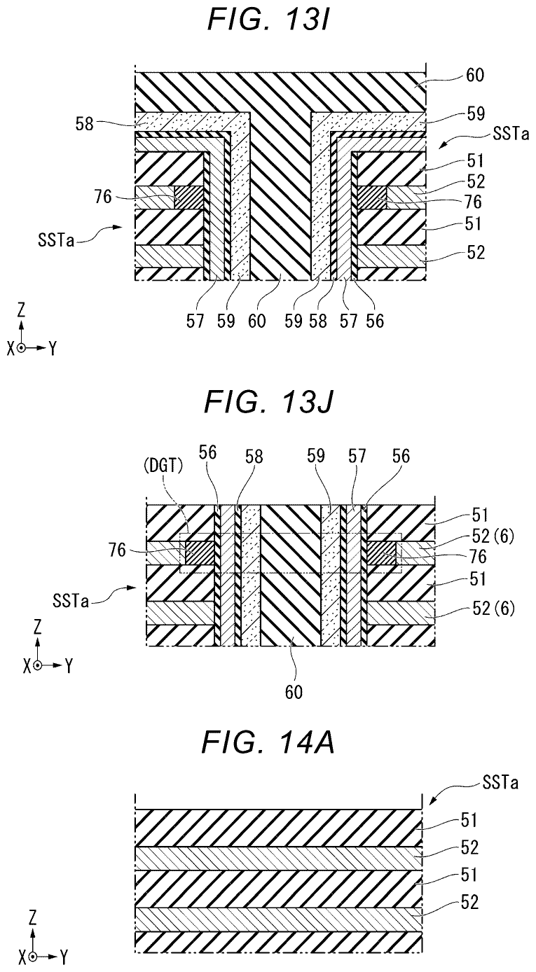

FIGS. 13A to 13J illustrate a first example of a manufacturing method of the semiconductor memory device according to the second embodiment. FIGS. 13A to 13J are sectional views illustrating an example of a manufacturing method related to a structure of the semiconductor memory device according to the second embodiment.

In advance of a process illustrated in FIG. 13A, processes of forming the peripheral circuit 100 on the substrate SUB and depositing the interlayer insulating film 81 and the conductive layer 3 are performed similarly to the above-described manufacturing method. Processes illustrated in FIGS. 13A and 13B are the same as the processes illustrated in FIGS. 11A and 11B in the above-described manufacturing method.

As in the structure illustrated in FIG. 11A, FIG. 13A illustrates a state in which the first insulating layers 51 and the second insulating layers 52 are alternately deposited a plurality of times to form the stacked body SSTa.

As in the process illustrated in FIG. 11B above, FIG. 13B illustrates a state in which the resist pattern 53 is formed on the uppermost first insulating layer 51 of the stacked body SSTa.

In a process illustrated in FIG. 13C, anisotropic etching such as RIE is executed using the resist pattern 53 as a mask to form a hole 72 penetrating the uppermost first insulating layer 51 and the uppermost second insulating layer 52.

In a process illustrated in FIG. 13D, a recess process of etching and retreating an inner surface of the second insulating layer 52 exposed in the hole 72 is executed. By the recess process, a recess 52A is formed on the inner surface of the hole 72. The recess 52A is formed at a position of the second insulating layer 52 in the hole 72 receding away from a central axis of the hole 72 relative to the inner surface of the hole 72. For example, etching may be executed using an etchant that can etch only the second insulating layer 52 and does not etch the first insulating layer 51, or wet etching may be executed using an etchant with a high etching selectivity ratio for the second insulating layer 52. A depth of the recess 52A can be adjusted according to an etching time.

In a process illustrated in FIG. 13E, anisotropic etching such as RIE is executed using the resist pattern 53 as a mask, thereby forming a memory hole 73 penetrating the stacked body SSTa and reaching the conductive layer 3. Since an upper portion of the memory hole 73 is connected to the hole 72, the hole 72 will be described below as a part of the memory hole 73.

In a process illustrated in FIG. 13F, the resist pattern 53 is peeled off. In a process illustrated in FIG. 13G, an insulating film 75 is formed on an inner surface of the memory hole 73 and the upper surface of the stacked body SSTa. The insulating film 75 is formed to fill the recess 52A and to be deposited on the inner surface of the memory hole 73 with a predetermined thickness.

In a process illustrated in FIG. 13H, the insulating film 75 on the inner surface of the memory hole 73 and the insulating film 75 on the upper surface of the stacked body SSTa are removed by etching except for the insulating film 75 in the recess 52A. When an etching time is adjusted, etching can be executed so that the insulating film 75 remains inside the recess 52A. A third insulating film 76 is formed by the insulating film 75 remaining in the recess 52A. The third insulating film 76 is formed in an annular shape surrounding a circumferential direction of the memory hole 73 inside the uppermost second insulating layer 52.

In a process illustrated in FIG. 13I, similarly to film formation in the process illustrated in FIG. 11E, the insulating film 56, the ferroelectric film 57, the insulating film 58, the semiconductor film 59, and the core film 60 are sequentially formed on the stacked body SSTa including the memory hole 73. By the film forming process, inside of the memory hole 55 is filled with the insulating film 56, the ferroelectric film 57, the insulating film 58, the semiconductor film 59, and the core film 60 as illustrated in FIG. 13I.

In a process illustrated in FIG. 13J, chemical mechanical polishing (CMP) is executed to remove the films deposited on the upper surface side of the stacked body SSTa. CMP is executed until the uppermost insulating layer 51 of the stacked body SSTa is exposed.

In the process illustrated in FIG. 13J, a structure in which inside of the memory hole 55 is filled with the insulating film 56, the ferroelectric film 57, the insulating film 58, the semiconductor film 59, and the core film 60 is obtained.

When the memory hole 55 is, for example, cylindrical, the semiconductor film 59, the insulating film 58, the ferroelectric film 57, and the insulating film 56 are formed in cylindrical shapes surrounding the columnar core film 60 with a predetermined thickness centering on the core film 60. The third insulating film 76 surrounding the insulating film 56 in an annular shape is formed inside the uppermost second insulating layer 52.

In a structure illustrated in FIG. 13J, when a replacement process of replacing the second insulating layer 52 with the conductive layer 6 and forming the select transistor DGT is executed, the third insulating film 76 that is not polarized is formed in the select transistor DGT instead of the ferroelectric film 57. As a result, in the select transistor DGT, threshold voltage modulation (Vth modulation) caused by polarization reversal and charge trapping can be prevented. Therefore, it is possible to implement the select transistor DGT in which change in the threshold voltage is prevented. Accordingly, it is possible to provide the semiconductor memory device 1 in which erroneous reading is prevented and variation in speed performance is small.

### Second Example of Manufacturing Method According to Second Embodiment

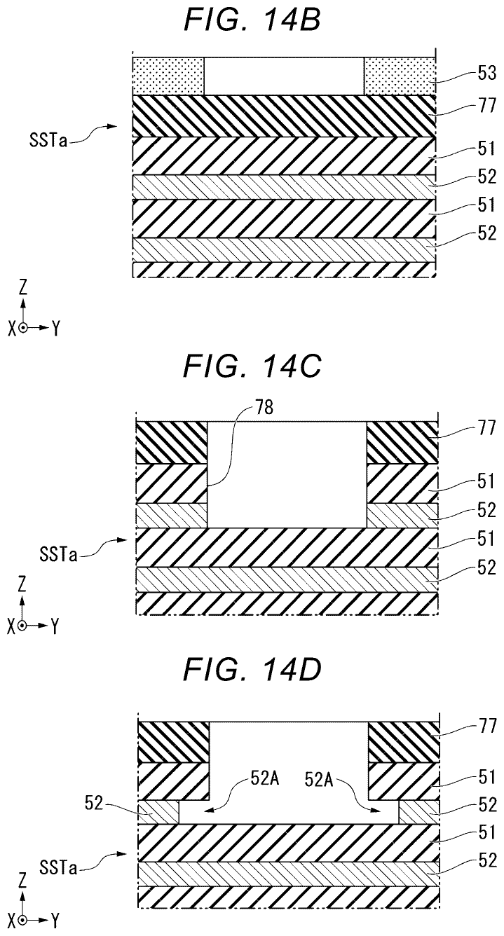

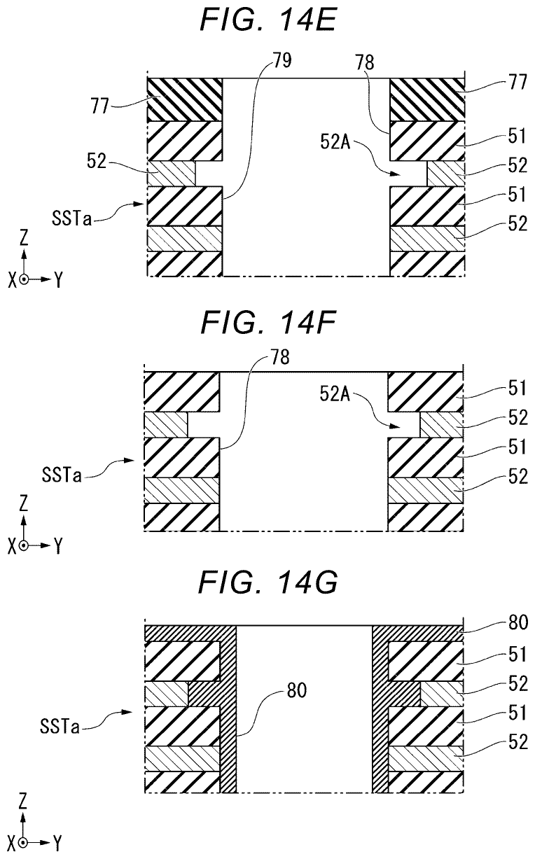

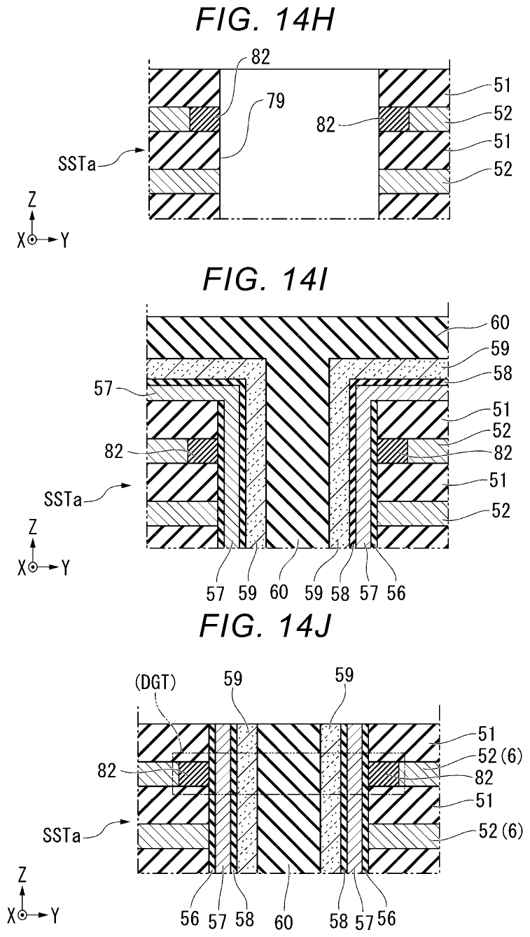

FIGS. 14A to 14J illustrate a second example of a manufacturing method for the semiconductor memory device according to the second embodiment. FIGS. 14A to 14J are sectional views illustrating an example of a manufacturing method related to a structure of the semiconductor memory device according to the second embodiment.

In advance of a process illustrated in FIG. 14A, processes of forming the peripheral circuit 100 on the substrate SUB and depositing the interlayer insulating film 81 and the conductive layer 3 are performed similarly to the above-described manufacturing method. The process illustrated in FIG. 14A is the same as the process illustrated in FIG. 11A in the manufacturing method above.

As in the structure illustrated in FIG. 11A, FIG. 14A illustrates a state in which the first insulating layers 51 and the second insulating layers 52 are alternately deposited a plurality of times to form the stacked body SSTa.

In a process illustrated in FIG. 14B, unlike the process illustrated in FIG. 11B above, the resist pattern 53 is formed after forming a hard mask 77 on the stacked body SSTa.

In a process illustrated in FIG. 14C, a pattern is transferred on the hard mask 77 using the resist pattern 53 as a mask, anisotropic etching such as RIE is executed via the hard mask 77, and a hole 78 penetrating the uppermost first insulating layer 51 and the uppermost second insulating layer 52 is formed.

In a process illustrated in FIG. 14D, a recess process of etching and retreating the inner surface of the second insulating layer 52 exposed in the hole 78 is executed. By the recess process, the recess 52A is formed on an inner surface of the hole 78. The recess 52A is formed at a position of the second insulating layer 52 in the hole 78 receding away from a central axis of the hole 78 relative to the inner surface of the hole 78. For example, etching may be executed using an etchant that can etch only the second insulating layer 52 and does not etch the first insulating layer 51, or wet etching may be executed using an etchant with a high etching selectivity ratio for the second insulating layer 52. A depth of the recess 52A can be adjusted according to an etching time.

In a process illustrated in FIG. 14E, anisotropic etching such as RIE is executed using the hard mask 77 as a mask, thereby forming a memory hole 79 penetrating the stacked body SSTa and reaching the conductive layer 3. Since an upper portion of the memory hole 79 is connected to the hole 78, the hole 78 will be described below as a part of the memory hole 79. By using the hard mask 77, an advantage that inside of the device is not contaminated compared to when only the resist pattern 53 is used is obtained, but the process may also be executed using only the resist pattern 53.

In a process illustrated in FIG. 14F, the hard mask 77 is peeled off. In a process illustrated in FIG. 14G, an insulating film 80 is formed on an inner surface of the memory hole 79 and the upper surface of the stacked body SSTa. The insulating film 80 is formed to fill the recess 52A and to be deposited on the inner surface of the memory hole 73 with a predetermined thickness.

In a process illustrated in FIG. 14H, the insulating film 80 on the inner surface of the memory hole 79 and the insulating film 80 on the upper surface of the stacked body SSTa are removed by etching except for the insulating film 80 in the recess 52A. When an etching time is adjusted, etching can be executed such that the insulating film 80 remains inside the recess 52A. A third insulating film 82 is formed by the insulating film 80 remaining in the recess 52A. The third insulating film 82 is formed in an annular shape surrounding a circumferential direction of the memory hole 79 inside the uppermost second insulating layer 52.

In a process illustrated in FIG. 14I, similarly to film formation in the process illustrated in FIG. 11E, the insulating film 56, the ferroelectric film 57, the insulating film 58, the semiconductor film 59, and the core film 60 are sequentially formed on the stacked body SSTa including the memory hole 79. By the film forming process, as illustrated in FIG. 14I, inside of the memory hole 79 is filled with the insulating film 56, the ferroelectric film 57, the insulating film 58, the semiconductor film 59, and the core film 60.

In a process illustrated in FIG. 14J, chemical mechanical polishing (CMP) is executed to remove the films deposited on the upper surface side of the stacked body SSTa. CMP is executed until the uppermost insulating layer 51 of the stacked body SSTa is exposed.

In a structure illustrated in FIG. 14J, when a replacement process of replacing the second insulating layer 52 with the conductive layer 6 and forming the select transistor DGT is executed, the third insulating film 82 that is not polarized is formed in the select transistor DGT instead of the ferroelectric film 57. Therefore, in the select transistor DGT, threshold voltage modulation (Vth modulation) due to polarization reversal and charge trapping can be prevented. Therefore, it is possible to implement the select transistor DGT in which change in the threshold voltage is prevented. Accordingly, it is possible to provide the semiconductor memory device 1 in which erroneous reading is prevented and variation in speed performance is small.

### Third Example of Manufacturing Method According to Second Embodiment

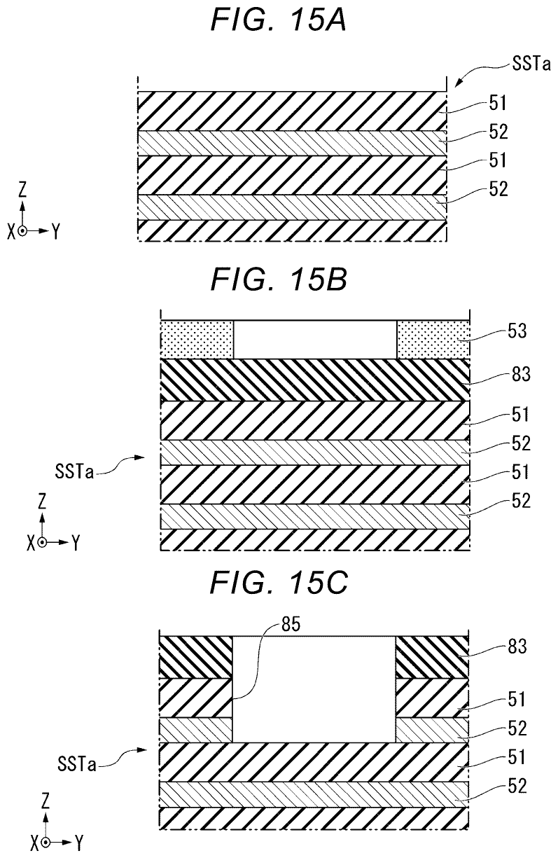

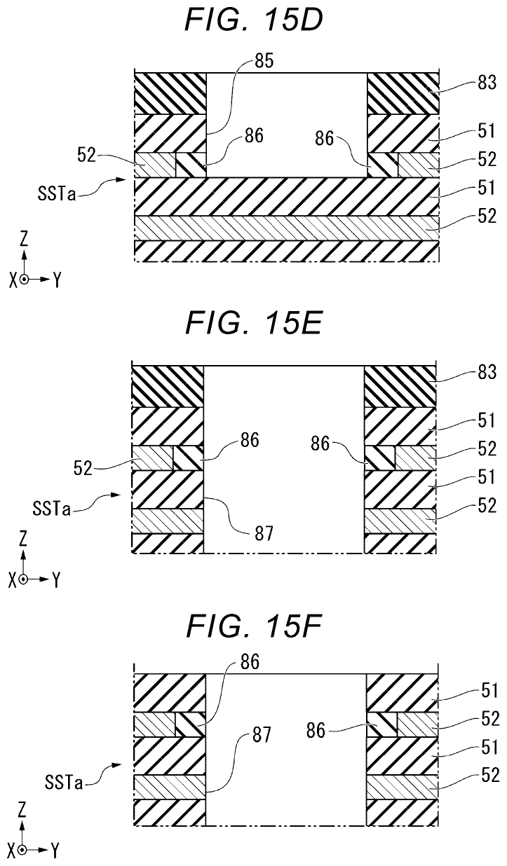

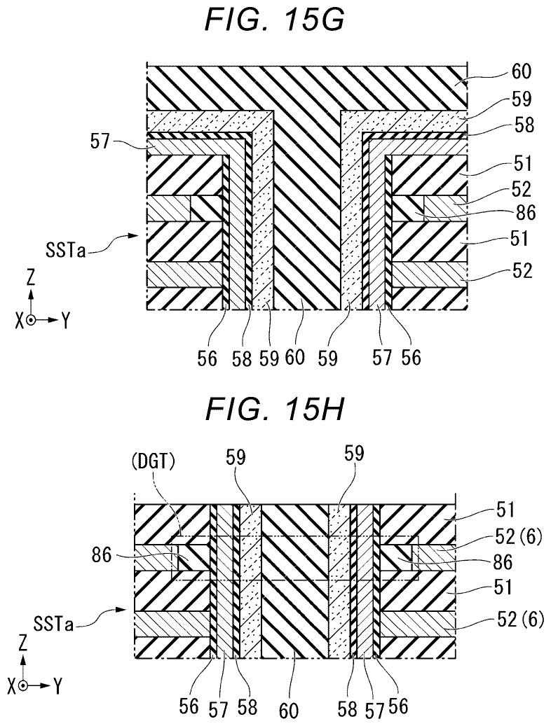

FIGS. 15A to 15H illustrate a third example of a manufacturing method for the semiconductor memory device according to the second embodiment. FIGS. 15A to 15H are sectional views illustrating an example of a manufacturing method related to a structure of the semiconductor memory device according to the second embodiment.

In advance of a process illustrated in FIG. 15A, processes of forming the peripheral circuit 100 on the substrate SUB and depositing the interlayer insulating film 81 and the conductive layer 3 are performed similarly to the above-described manufacturing method. The process illustrated in FIG. 15A is the same as the process illustrated in FIG. 11A in the above-described manufacturing method.

As in the structure illustrated in FIG. 11A, FIG. 15A illustrates a state in which the first insulating layers 51 and the second insulating layers 52 are alternately deposited a plurality of times to form the stacked body SSTa.

In a process illustrated in FIG. 15B, unlike the process illustrated in FIG. 11B above, the resist pattern 53 is formed after forming a hard mask 83 on the stacked body SSTa.

In a process illustrated in FIG. 15C, a hole pattern is transferred to the hard mask 83 using the resist pattern 53 as a mask, anisotropic etching such as RIE is executed via the hard mask 83, a hole 85 penetrating the uppermost first insulating layer 51 and the uppermost second insulating layer 52 is formed, and the resist pattern 53 is removed.

In a process illustrated in FIG. 15D, an oxidation process of oxidizing the inner surface of the second insulating layer 52 exposed in the hole 85 is executed. By the oxidation process, the second insulating layer 52 located on an inner surface of the hole 85 is oxidized to form a third insulating film 86. As an example, when the first insulating layer 51 is configured with silicon oxide and the second insulating layer 52 is configured with silicon nitride, the second insulating layer 52 exposed on the inner surface of the hole 85 is oxidized into silicon oxide.

The third insulating film 86 is formed with a predetermined thickness in a direction receding away from the central axis of the hole 85 with respect to the inner surface of the hole 85 (Y direction) at the position of the second insulating layer 52 in the hole 85. A thickness of the third insulating film 86 in the Y direction may be adjusted according to a time of the oxidation process.

In a process illustrated in FIG. 15E, anisotropic etching such as RIE is executed using the hard mask 83 as a mask, thereby forming a memory hole 87 penetrating the stacked body SSTa and reaching the conductive layer 3. Since an upper portion of the memory hole 87 is connected to the hole 85, the hole 85 will be described below as a part of the memory hole 87.

In a process illustrated in FIG. 15F, the hard mask 83 is peeled off.

In a process illustrated in FIG. 15G, similarly to film formation in the process illustrated in FIG. 11E, the insulating film 56, the ferroelectric film 57, the insulating film 58, the semiconductor film 59, and the core film 60 are sequentially formed on the stacked body SSTa including the memory hole 87. By the film forming process, as illustrated in FIG. 15G, inside of the memory hole 87 is filled with the insulating film 56, the ferroelectric film 57, the insulating film 58, the semiconductor film 59, and the core film 60.

In a process illustrated in FIG. 15H, chemical mechanical polishing (CMP) is executed to remove the films deposited on the upper surface side of the stacked body SSTa. CMP is executed until the uppermost insulating layer 51 of the stacked body SSTa is exposed.

In the structure illustrated in FIG. 15H, when a replacement process of replacing the second insulating layer 52 with the conductive layer 6 and forming the select transistor DGT is executed, the third insulating film 86 that is not polarized is formed in the select transistor DGT instead of the ferroelectric film. Therefore, in the select transistor DGT, threshold voltage modulation (Vth modulation) due to polarization reversal and charge trapping can be prevented. Therefore, it is possible to implement the select transistor DGT in which change in the threshold voltage is prevented. Accordingly, it is possible to provide the semiconductor memory device 1 including the memory cell array 50 in which erroneous reading is prevented and variation in speed performance is small.

Incidentally, in the above-described embodiments, an example of forming one select transistor DGT at a position closest to the bit line BL is described. When a plurality of transistors are formed as select transistors sequentially from the position closest to the bit line BL, it is preferable to apply the second insulating film ISF according to the first embodiment or apply the third insulating film 49 according to the second embodiment for each of the corresponding number of select transistors.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body in which a plurality of electrode layers are stacked in a stacking direction with an insulating layer interposed therebetween;
an electrode film extending in the stacking direction inside the stacked body;
a ferroelectric film and a first insulating film;
a bit line provided outside of the stacked body and connected to one end of the electrode film; and
a source line provided outside of the stacked body and connected to the other end of the electrode film, wherein
the stacked body includes a plurality of memory cells, in which a memory cell is provided at a position at which the electrode layer and the electrode film intersect each other and the ferroelectric film and the first insulating film are arranged between the electrode layer and the electrode film, and
in a memory cell closest to the bit line among the plurality of memory cells, a select transistor includes a second insulating film that is non-ferroelectric, and is provided between the electrode layer and the electrode film.

2. The semiconductor memory device according to claim 1, wherein
the electrode film has a cylindrical shape and extends in the stacking direction inside the stacked body,
the select transistor includes the second insulating film and the ferroelectric film that surround the electrode film, and
the select transistor includes a part of the electrode film extending inside the electrode film as a node.

3. The semiconductor memory device according to claim 1, wherein the ferroelectric film is an oxide film in an orthorhombic or rhombohedral crystal phase of which a main component is at least one of Hf or Zr.

4. The semiconductor memory device according to claim 1, wherein at least one of the first insulating film, the second insulating film, or the third insulating film is a silicon oxide film.

5. The semiconductor memory device according to claim 1, wherein the ferroelectric film includes a material of which a main component is hafnium oxide.

6. The semiconductor memory device according to claim 5, wherein the ferroelectric film includes a material further containing at least one element selected from the group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

7. The semiconductor memory device according to claim 1, wherein the select gate line SGD does not include the ferroelectric film.

8. A semiconductor memory device comprising:
a stacked body in which a plurality of electrode layers are stacked in a stacking direction with an insulating layer interposed therebetween;
an electrode film extending in the stacking direction inside the stacked body;
a ferroelectric film and a first insulating film;
a bit line provided outside of the stacked body and connected to one end of the electrode film; and
a source line provided outside of the stacked body and connected to the other end of the electrode film, wherein
the stacked body includes a plurality of memory cells in which a memory cell is provided at a position at which the electrode layer and the electrode film intersect each other and the ferroelectric film and the first insulating film are arranged between the electrode layer and the electrode film, and
in the memory cell closest to the bit line among the plurality of memory cells, a select transistor includes the ferroelectric film and a third insulating film thicker than the first insulating film, and is provided between the electrode layer and the electrode film.

9. The semiconductor memory device according to claim 8, wherein the ferroelectric film is an oxide film in an orthorhombic or rhombohedral crystal phase of which a main component is at least one of Hf or Zr.

10. The semiconductor memory device according to claim 8, wherein at least one of the first insulating film, the second insulating film, or the third insulating film is a silicon oxide film.

11. The semiconductor memory device according to claim 8, wherein the ferroelectric film includes a material of which a main component is hafnium oxide.

12. The semiconductor memory device according to claim 11, wherein the material of the ferroelectric film further contains at least one element selected from the group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

13. The semiconductor memory device according to claim 8, wherein the third insulating film is at least 1.3 times thicker than the first insulating film.

14. A method of manufacturing a semiconductor memory device, comprising:
forming a stacked body by alternately stacking a plurality of electrode layers and insulating layers on a substrate in a stacking direction;
forming a plurality of memory holes through the stacked body, each memory hole extending in the stacking direction and reaching a conductive layer that functions as a source line;
forming, within each memory hole, a core member along a central axis, a semiconductor film to surround the core member, an inner insulating film to surround the semiconductor film, a ferroelectric film to surround the inner insulating film, and a first insulating film to surround the ferroelectric film;
forming a bit line connected to one end of the semiconductor film and the source line connected to the other end of the semiconductor film;
forming a memory cell at a position where the electrode layer and the semiconductor film intersect via the ferroelectric film and the first insulating film;
forming a select transistor at a position closer to the bit line than to the source line, the select transistor including the ferroelectric film and a third insulating film that is thicker than the first insulating film, to reduce an electric field applied to the ferroelectric film.

15. The method according to claim 14, where the third insulating film is formed outside the first insulating film.

16. The method according to claim 14, wherein the ferroelectric film is an oxide film in an orthorhombic or rhombohedral crystal phase of which a main component is at least one of Hf or Zr.

17. The method according to claim 14, wherein at least one of the first insulating film, the second insulating film, or the third insulating film is a silicon oxide film.

18. The method according to claim 14, wherein the ferroelectric film includes a material of which a main component is hafnium oxide.

19. The method according to claim 18, wherein the material of the ferroelectric film further contains at least one element selected from the group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

20. The semiconductor memory device according to claim 14, wherein the third insulating film is at least 1.3 times thicker than the first insulating film.
